(19) United States
(12) Patent Application Publication
(10) Pub. No.: US 2025/0377395 A1
(43) Pub. Date: Dec. 11, 2025

(54) SYSTEM AND METHOD OF COMPENSATING FOR NOISE INTRODUCED BY TEST INSTRUMENT WHEN MEASURING DEVICE UNDER TEST (DUT)

(71) Applicant: KEYSIGHT TECHNOLOGIES, INC., SANTA ROSA, CA (US)

(72) Inventors: Tian-Sheng Zhang, Beijing (CN); Yan-Zhao Wu, Beijing (CN); Wen Jau Tai, Penang (MY); Soo Yi Koay, Penang (MY)

(21) Appl. No.: 19/092,066

(22) Filed: Mar. 27, 2025

(30) Foreign Application Priority Data
Jun. 6, 2024 (CN) 202410732491.2

(51) Int. Cl. G01R 29/08

(52) U.S. Cl. CPC G01R 29/0878

(57) ABSTRACT

A system for compensating for noise from by a test instrument measuring a signal from a DUT includes a processing unit and a memory storing instructions that cause the processing unit to receive a digital baseband signal from the test instrument including an ideal signal and a total noise signal including DUT noise from the DUT and instrument noise from the test instrument; perform coherent averaging of the digital baseband signal to determine estimated ideal signal I/Q components; determine estimated total noise I/Q components; estimate noise power of the instrument noise introduced by the test instrument using a noise figure extension (NFE) model; and determine corrected noise I/Q components of the digital baseband signals based on a ratio of estimated noise power of the DUT and the total noise power of the digital baseband signals; and combine the estimated ideal signal I/Q components and the corrected noise I/Q components.

### PRIORITY

This application claims priority under 35 U.S.C. § 119 to Chinese Patent Application No. 202410732491.2, filed on Jun. 6, 2024, which is hereby specifically incorporated by reference in its entirety.

### BACKGROUND

When performing measurements of radio frequency (RF) signals output by a device under test (DUT), test instruments such as signal analyzers, vector network analyzers (VNAs) and oscilloscopes may contribute noise to the RF signal, particularly during digitization. Such noise contributed by the test instruments causes inaccuracies when measuring various attributes of the DUT, such as error vector magnitude (EVM), for example.

EVM, in particular, may be considered a measure of how far actual constellation points of an RF signal are deviating from their ideal locations. That is, a digitally-modulated RF signal transmitted by an ideal RF transmitter would have all constellation points precisely at their ideal locations. However, with real RF devices and systems, various factors in the implementation, such as modulation distortion, phase noise, carrier leakage and low image rejection ratio, may cause the actual constellation points to deviate from their ideal locations. EVM is a measurement of such deviations.

Recent developments in cellular and wireless local area network (WLAN) standards are trending towards higher signal bandwidths and higher modulation schemes. Accordingly, EVM requirements of DUTs are becoming more and more stringent. For example, the Wi-Fi 7 (802.11be) standard requires a maximum bandwidth of 320 MHz and modulation schemes up to 4096QAM. The noise floor introduced from a signal analyzer brings a growing impact on the final EVM.

FIG. 1 is a simplified block diagram showing noise contributed by a DUT 110 and a signal analyzer 120 used for measuring the output of the DUT 110. Both the DUT noise introduced by the DUT 110 and the instrument noise introduced by the signal analyzer 120 while measuring an RF signal output by the DUT 110 contribute to final EVM (EVM_{final}=EVM_{DUT}+EVM_{SA}). The final EVM does not truly reflect the RF performance of the DUT 110 because the signal analyzer 120 contributes to a considerable proportion of the final EVM. Therefore, it is important to remove the contributions from the signal analyzer 120 to the final EVM.

However, conventional techniques for determining noise contributed by the signal analyzer 120 are time consuming and complicated. For example, load-terminated based noise correction requires the signal analyzer 120 to be physically switched to a terminated input so that the noise power of the signal analyzer 120 can be measured in isolation from the DUT 110. Such a technique requires additional steps of pausing the measurement process, disconnecting the DUT 110 from the signal analyzer 120, terminating the input of the signal analyzer 120 to a load (e.g., a 50 ohm termination), measuring the noise contributed by the signal analyzer 120, and then reconnecting the DUT 110 to reconvene testing.

What is needed is important a noise correction technique to estimate accurate noise power of the signal analyzer 120 without changing connections and using the same settings for measuring RF signals from the DUT 110. This would enable measuring EVM of the DUT 110, for example, without influence from noise introduced by the signal analyzer 120 during the measurement process, while maintaining connections with the DUT 110 and configurations of the signal analyzer 120. It is important in noise correction of in-phase/90 degree out-of-phase (I/Q) signals to estimate the accurate noise power of the signal analyzer without changing connections and at the same settings. Accordingly, a system is provided for measuring EVM of a DUT without influence from noise introduced by the signal analyzer during the measurement process, while maintain DUT connections and signal analyzer configurations.120.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is a simplified block diagram of a conventional test system for measuring a test signal received form a DUT using a signal analyzer.

FIG. 2A is a simplified block diagram of a test system for compensating for noise introduced by a signal analyzer configured to measure a test signal received from DUT, according to a representative embodiment.

FIG. 2B is a simplified block diagram of a portion of an illustrative heterodyne I/Q receiver, as would be included in the signal analyzer of the test system, according to a representative embodiment.

FIG. 3 is a simplified block diagram showing a mathematical model applied by a noise floor extension (NFE) module of the test system, according to a representative embodiment.

FIG. 4 is a flow diagram illustrating a method of compensating for noise introduced by a signal analyzer configured to measure a test signal received from DUT, according to a representative embodiment.

FIG. 5 is a simplified block diagram of a representative processing unit, according to a representative embodiment.

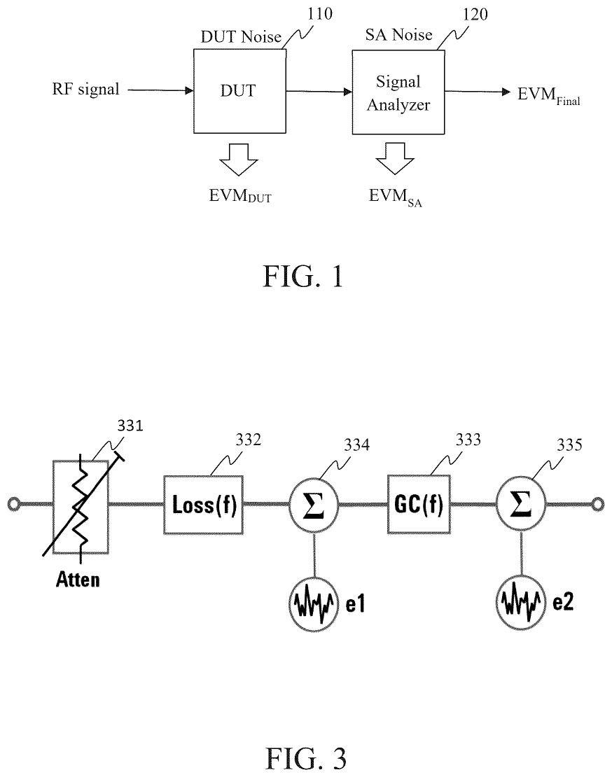

### DETAILED DESCRIPTION

In the following detailed description, for purposes of explanation and not limitation, representative embodiments disclosing specific details are set forth in order to provide a thorough understanding of an embodiment according to the present teachings. Descriptions of known systems, devices, materials, methods of operation and methods of manufacture may be omitted so as to avoid obscuring the description of the representative embodiments. Nonetheless, systems, devices, materials and methods that are within the purview of one of ordinary skill in the art are within the scope of the present teachings and may be used in accordance with the representative embodiments. It is to be understood that the terminology used herein is for purposes of describing particular embodiments only and is not intended to be limiting. The defined terms are in addition to the technical and scientific meanings of the defined terms as commonly understood and accepted in the technical field of the present teachings.

It will be understood that, although the terms first, second, third etc. may be used herein to describe various elements or components, these elements or components should not be limited by these terms. These terms are only used to distinguish one element or component from another element or component. Thus, a first element or component discussed below could be termed a second element or component without departing from the teachings of the present disclosure.

The terminology used herein is for purposes of describing particular embodiments only and is not intended to be limiting. As used in the specification and appended claims, the singular forms of terms “a,” “an” and “the” are intended to include both singular and plural forms, unless the context clearly dictates otherwise. Additionally, the terms “comprises,” and/or “comprising,” and/or similar terms when used in this specification, specify the presence of stated features, elements, and/or components, but do not preclude the presence or addition of one or more other features, elements, components, and/or groups thereof. As used herein, the term “and/or” includes any and all combinations of one or more of the associated listed items.

Unless otherwise noted, when an element or component is said to be “connected to,” “coupled to,” or “adjacent to” another element or component, it will be understood that the element or component can be directly connected or coupled to the other element or component, or intervening elements or components may be present. That is, these and similar terms encompass cases where one or more intermediate elements or components may be employed to connect two elements or components. However, when an element or component is said to be “directly connected” to another element or component, this encompasses only cases where the two elements or components are connected to each other without any intermediate or intervening elements or components.

The present disclosure, through one or more of its various aspects, embodiments and/or specific features or sub-components, is thus intended to bring out one or more of the advantages as specifically noted below. For purposes of explanation and not limitation, example embodiments disclosing specific details are set forth in order to provide a thorough understanding of an embodiment according to the present teachings. However, other embodiments consistent with the present disclosure that depart from specific details disclosed herein remain within the scope of the appended claims. Moreover, descriptions of well-known apparatuses and methods may be omitted so as to not obscure the description of the example embodiments. Such methods and apparatuses are within the scope of the present disclosure.

The various embodiments are in the technical field of measuring and testing signals from electrical devices, and are directed to removing noise contributed by a test instrument, such as a signal analyzer, while measuring an RF test signal (or signal under test (SUT)) at the output of the DUT in order to perform measurements of the RF test signal with only noise introduced by the DUT itself. Removing the noise introduced by the test instrument ensures fidelity of the measurements of the RF test signal, thereby improving accuracy of the same. Various types of measurements improved by the various embodiments include measuring error vector magnitude (EVM) of the DUT.

According to a representative embodiment, a system is provided for compensating for noise introduced by a test instrument configured to measure an RF test signal received from a DUT, where the RF test signal is modulated by test data of the DUT. The system includes a processing unit and a memory storing instructions that, when executed, cause the processing unit to receive a digital baseband signal with repeating waveforms output by the test instrument in response to the RF test signal received by the test instrument, where the digital baseband signal includes an ideal signal and a total noise signal, where the total noise signal includes DUT noise introduced by the DUT and instrument noise introduced by the test instrument; perform coherent averaging of the repeating waveforms of the digital baseband signal to determine estimated ideal signal in-phase/quadrature (I/Q) components, where the estimated ideal signal I/Q components have negligible noise; determine estimated total noise I/Q components of the digital baseband signal by subtracting the estimated ideal signal I/Q components from the digital baseband signal; determine total noise power of the digital baseband signal based on the estimated total noise I/Q components; estimate noise power of the instrument noise in the digital baseband signal introduced by the test instrument using a noise figure extension (NFE) model based on at least settings of the test instrument; determine corrected noise I/Q components of the digital baseband signal by determining a noise power ratio of estimated noise power of the DUT and the total noise power of the digital baseband signal, and applying the noise power ratio to the estimated total noise I/Q components; and combine the estimated ideal signal I/Q components and the corrected noise I/Q components to provide a corrected digital baseband signal that indicates noise only introduced by the DUT, where the corrected digital baseband signal is demodulated to provide the test data of the DUT. The instructions may further cause the processing unit to measure EVM of the demodulated corrected digital baseband signal of the DUT, wherein the measured EVM provides an actual EVM of the DUT.

According to another representative embodiment, a method is provided for compensating for noise introduced by a test instrument configured to measure an RF test signal received from a DUT, where the RF test signal is modulated by test data of the DUT. The method includes receiving a digital baseband signal with repeating waveforms output by the test instrument in response to the RF test signal received by the test instrument, where the digital baseband signal includes an ideal signal and a total noise signal, and where the total noise signal includes DUT noise introduced by the DUT and instrument noise introduced by the test instrument; performing coherent averaging of the repeating waveforms of the digital baseband signal to determine estimated ideal I/Q components, where the estimated ideal signal I/Q components have negligible noise; determining estimated total noise I/Q components of the digital baseband signal by subtracting the estimated ideal signal I/Q components from the digital baseband signal; determining total noise power of the digital baseband signal based on the estimated total noise I/Q components; estimating noise power of the instrument noise in the digital baseband signal introduced by the test instrument using an NFE model based on at least settings of the test instrument; determining corrected noise I/Q components of the digital baseband signal by determining a noise power ratio of estimated noise power of the DUT and the total noise power of the digital baseband signal, and applying the noise power ratio to the estimated total noise I/Q components; and combining the estimated ideal signal I/Q components and the corrected noise I/Q components to provide a corrected digital baseband signal that indicates noise only introduced by the DUT, where the corrected digital baseband signal is demodulated to provide the test data of the DUT. The method may further include measuring EVM of the demodulated corrected digital baseband signal of the DUT, wherein the measured EVM provides an actual EVM of the DUT.

According to another representative embodiment, a non-transitory computer readable medium stores instructions for compensating for noise introduced by a test instrument configured to measure an RF test signal received from a DUT, where the RF test signal is modulated by test data of the DUT. When executed by a processing unit, the instructions cause the processing unit to receive a digital baseband signal with repeating waveforms output by the test instrument in response to the RF test signal received by the test instrument, where the digital baseband signal includes an ideal signal and a total noise signal, and where the total noise signal includes DUT noise introduced by the DUT and instrument noise introduced by the test instrument; perform coherent averaging of the repeating waveforms of the digital baseband signal to determine estimated ideal signal I/Q components, where the estimated ideal signal I/Q components have negligible noise; determine estimated total noise I/Q components of the digital baseband signal by subtracting the estimated ideal signal I/Q components from the digital baseband signal; determine total noise power of the digital baseband signal based on the estimated total noise I/Q components; estimate noise power of the instrument noise in the digital baseband signal introduced by the test instrument using a noise figure extension (NFE) model based on at least settings of the test instrument; determine corrected noise I/Q components of the digital baseband signal by determining a noise power ratio of estimated noise power of the DUT and the total noise power of the digital baseband signal, and applying the noise power ratio to the estimated total noise I/Q components; and combine the estimated ideal signal I/Q components and the corrected noise I/Q components to provide a corrected digital baseband signal that indicates noise only introduced by the DUT, and where the corrected digital baseband signal is demodulated to provide the test data of the DUT.

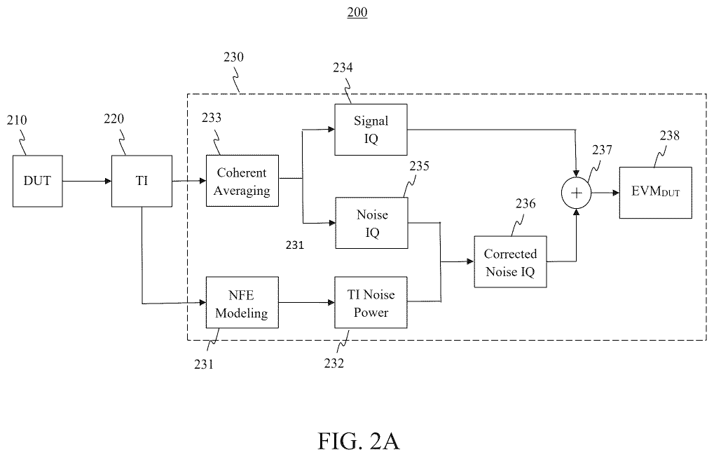

FIG. 2A is a simplified block diagram of a test system for compensating for noise introduced by a signal analyzer configured to measure a test signal received from DUT, according to a representative embodiment.

Referring to FIG. 2A, test system 200 includes a test instrument (TI), depicted as a signal analyzer 220 for purposes of illustration, which is configured to receive an RF test signal output by the DUT 210 for measuring properties of the DUT 210, where the RF test signal may be referred to as the signal under test (SUT). Generally, the RF test signal is modulated by test data of the DUT 210, e.g., for indicating performance thereof. Although the test system 200 is shown with the signal analyzer 220 as the test instrument, it is understood that the test system 200 may include any other type of test instrument that provides digital baseband I/Q signals when measuring SUTs, such as spectrum analyzers, vector network analyzers (VNAs) or oscilloscopes, without departing from the scope of the present teachings. The noise compensation described herein effectively extends the noise floor of the signal analyzer 220 when measuring various attributes of the DUT 210, such as EVM, for example, indicating quality of the RF test signal transmitted by the DUT 210. Generally, as signal bandwidths in communication systems become wider, EVM requirements have become very strict. For example, according to the Wi-Fi 7 standard, when the signal bandwidth is 320 MHz, EVM must be less than −49 dB. Also, the noise introduced by the signal analyzer 220 as a proportion of total noise becomes larger, and thus cannot be ignored when measuring EVM of the RF test signal.

The RF test signal output by the DUT 210 may be generated by the DUT 210, e.g., when the DUT 210 is an arbitrary waveform generator (AWG) or other signal source, or may be provided by the DUT 210 in response to an input stimulus signal. The RF test signal is a periodic waveform with a set frequency and bandwidth.

The signal analyzer 220 is configured to mix the RF test signal with a complex sinusoidal signal at an I/Q mixer to provide in-phase/quadrature (I/Q) components. FIG. 2B is a simplified block diagram of a portion of an illustrative heterodyne I/Q receiver, as would be included in the signal analyzer 220 in the test system 200, according to a representative embodiment.

Referring to FIG. 2B, the illustrative heterodyne I/Q receiver of the signal analyzer 220 includes a low noise amplifier (LNA) 215 that receives and amplifies the RF test signal output by the DUT 210. The amplified RF test signal is split into first and second signal paths. The first signal path includes first mixer 221, first low path filter (LPF) 222 and first analog to digital converter (ADC) 223, and the second signal path includes second mixer 224, second LPF 225 and second ADC 226.

A local oscillator (LO) 227 generates an LO signal at an LO frequency for down-converting the RF test signal to in-phase and quadrature (I/Q) components at an intermediate frequency (IF). That is, the LO signal is input to the first mixer 221 in the first path, which mixes the LO signal with the carrier frequency of the RF test signal to generate a down-converted in-phase component at the IF. The LO signal is also input to the second mixer 224, after undergoing a 90 degrees phase shift by the phase shifter 228, which mixes the phase-shifted LO signal with the carrier frequency of RF test signal to generate a down-converted quadrature component at the IF. The frequency down-converted in-phase component is low-pass filtered by the first LPF 222, and is sampled and digitized by the first ADC 223. The frequency down-converted quadrature component is low-pass filtered by the second LPF 225, and is sampled and digitized by the second ADC 226. The digitized in-phase and quadrature components are combined by adder 229 and output as a digital baseband I/Q signal. When the intermediate frequency is not zero, the process may include additional frequency down-conversion to provide the digital baseband I/Q signal, as would be apparent to one skilled in the art.

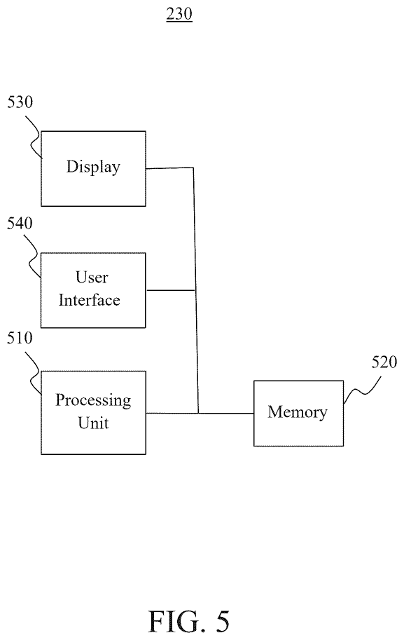

Referring again to FIG. 2A, the digital baseband I/Q signal is provided to a processing unit 230. The processing unit 230 may be included as a part of the signal analyzer 220, may be another computing device, or may be a combination of both, without departing from the scope of the present teachings. The processing unit 230 may be a digital signal processor (DSP), for example, as discussed in more detail below with reference to FIG. 5. For ease of explanation, the processing unit 230 is depicted as separate software/firmware modules with corresponding functions, although it is understood that the depicted arrangement of these functions is not limiting.

The processing unit 230 includes noise floor extension (NFE) module 231, which estimates instrument noise power of the signal analyzer 220. Generally, the estimated instrument noise power is used to determine the proportion of total noise of the digital baseband I/Q signal that is attributable to the DUT 210. To do this, the estimated instrument noise power of the signal analyzer 220 is subtracted from the total noise power of the digital baseband I/Q signal to determine the noise power of the DUT 210. Then, a noise power ratio of the DUT noise power of the DUT 210 and the total noise power is determined, such that the noise attributable to the DUT 210 may then be determined by multiplying the total noise of the digital baseband I/Q signal by the noise power ratio, as discussed below.

In order to determine the instrument noise power of the signal analyzer 220, settings data from the signal analyzer 220 are input to the NFE module 231. The settings data includes measurement settings, which are settings of the signal analyzer 220 entered by the user for a particular test, e.g., via front panel keys, and calibration data obtained during calibration of the signal analyzer 220 prior to the test, where selection of settings and performance of calibration for various types of testing and DUTs would be apparent to one skilled in the art. The NFE module 231 applies a mathematical model to the input settings data to estimate the instrument noise power of the signal analyzer 220, indicated by instrument noise power module 232, where the variables of the mathematical model depend at least in part on the settings data of the signal analyzer 220, as discussed below. Because the NFE module 231 applies a mathematical model based on the settings data, as opposed to the RF test signal output by the DUT 210, there is no need to disconnect the signal analyzer 220 from the DUT 210 and reconnect the signal analyzer 220 to a load in order to separately measure the instrument noise power, as is required in conventional systems. Therefore, the instrument noise power may be determined while the signal analyzer 220 is still measuring the RF test signal output by the DUT 210 in real-time, or may be determined and applied in post-processing.

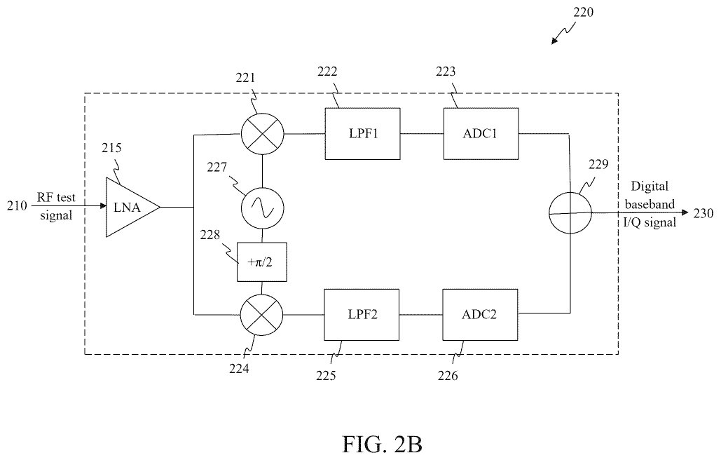

FIG. 3 is a simplified block diagram showing the mathematical model applied by the NFE module 231, according to a representative embodiment.

Referring to FIG. 3, the NFE module 231 includes attenuation (Atten) module 331, loss function (Loss(f)) module 332, and gain control function (GC(f)) module 333. The attenuation module 331 provides signal attenuation of the signal analyzer 220 as set by the user. The loss function module 332 provides a predetermined loss function indicating the signal path loss from an RF reference input plane to the downconverter mixer output plane of the signal analyzer 220. The signal path loss may be determined by the calibration data specific to user's settings, as provided by the settings data. The gain control function module 333 provides a predetermined gain control function indicting step attenuation to compensate for path loss at the front-end of the signal analyzer 220. The step attenuation is implemented as discrete steps as set by firmware of the signal analyzer 220 such that the step attenuation is inversely proportional to loss function, Loss(f). The predetermined loss function is retrieved and calculated from the calibration data, and the predetermined gain control function is controlled and determined by the signal analyzer 220 firmware, as the intention is to reverse the effect of signal path loss indicated by the loss function provided by the loss function module 332.

The attenuation, signal path loss, and step attenuation compensation are retrieved by the signal analyzer 220 firmware from the calibration data, and the values depend at least in part on actual operating conditions of the signal analyzer 220, e.g., indicated by the settings selected by the user on the front panel. The settings of the signal analyzer 220 used for the NFE model include at least center frequency, bandwidth, attenuation, preamplifier, IF path, and IF gain, for example. The values of the attenuation, loss function and the gain control function are retrieved and/or derived from the signal analyzer 220 calibration file based on the user's selected settings.

The NFE module 231 also includes a first adder 334 for summing front-end noise (e1) with the output of the loss function module 332 and a second adder 335 for summing back-end noise (e2) with the output of the gain control function module 333. The front-end noise is contributed by front-end hardware of the signal analyzer 220 prior to the ADCs discussed above, such as front-end amplifiers, attenuators and mixers. The back-end noise of the signal analyzer 220 is contributed primarily by the ADCs themselves. In an embodiment, the values of the front-end noise and the back-end noise are calculated for each major RF path by the signal analyzer firmware after a noise characterization alignment routine during the calibration, and are stored in calibration files for future use. These front-end noise and back-end noise values depend in part on the signal path settings of the signal analyzer 220.

The mathematical model of the NFE module 231 estimates the instrument noise power (\hat{p}_{TI}) at an RF reference input plane of the signal analyzer 220 according to Equation (1):

$${\hat{ρ}}_{TI} = \frac{1}{Loss ( f )} * \frac{1}{Atten} * [ e 1 + e 2 / GC ( f ) ] \qquad ( 1 )$$

In Equation (1), Atten is the signal attenuation, Loss(f) is the predetermined loss function, GC(f) is the predetermined gain function, e1 is the front-end noise, and e2 is the back-end noise, as discussed above. Ultimately, the instrument noise power (\hat{p}_{TI}) is subtracted from total noise power of the digital baseband I/Q signal (\hat{p}ₜₒₜₐₗ) to obtain the DUT noise power of the DUT 210 (\hat{p}_{DUT}), as discussed below.

Referring again to FIG. 2A, the digital baseband I/Q signal output by the signal analyzer 220 is input to a coherent averaging module 233. Like the RF test signal, the digital baseband I/Q signal is periodic, having repeating waveforms that correspond to the repeating waveforms of the periodic RF test signal. Therefore, the digital baseband I/Q signal (sₘ) may be written as shown by Equation (2):

$${s}_{m} = {s}_{ideal} ( {t}_{n} ) + {n}_{m} ( {t}_{n} ) \qquad ( 2 )$$

In Equation (2), s_{ideal}(tₙ) is a hypothetical ideal digital baseband I/Q signal with no noise, as would be output by the DUT 210, nₘ(tₙ) is the total noise in the actual digital baseband I/Q signal output by the signal analyzer 220, and tₙ is the nth sampling point.

The coherent averaging module 233 is configured to perform coherent averaging on the digital baseband I/Q signal. The coherently averaged digital baseband I/Q signal is separated into signal (signal I/Q) and noise (noise I/Q), indicated by the signal I/Q module 234 and the noise I/Q module 235, respectively. The signal I/Q is an estimated ideal signal (Ŝ_{ideal}(tₙ)), shown in Equation (4), which is subtracted from the digital baseband I/Q signal to separate out the noise I/Q signal (\hat{n}ₘ^{total}(tₙ)), shown in Equations 5A and 5B, below. That is, the signal I/Q provides an estimate of a noise-free RF test signal output by the DUT 210. The noise I/Q provides an estimate of the total noise introduced to the RF test signal by both the DUT 210 and the signal analyzer 220 measuring the RF test signal.

Assuming that the DUT noise and the instrument noise are thermal noise or AWG generated noise (AWGN), then the total noise may be written as the sum of the DUT noise and the instrument noise, shown in Equation (3):

$${n}^{total} ( {t}_{n} ) = {n}^{D U T} ( {t}_{n} ) + {n}^{TI} ( {t}_{n} ) \qquad ( 3 )$$

The coherent averaging module 233 is configured to perform coherent averaging over M repeating waveforms of the digital baseband I/Q signal, where M is a positive integer greater than 1. As part of the coherent averaging process, amplitudes of the M repeating waveforms in the digital baseband I/Q signal are initially synchronized or aligned with timing offset, phase offset and magnitude mismatch. This may be accomplished by cross-correlation with a reference signal or cross-correlation with a first repeating waveform, for example. The synchronized M repeated waveforms are then averaged to determine the coherently averaged digital baseband I/Q signal. As mentioned above, the coherent averaging over the synchronized M repeating waveforms provides estimated ideal signal I/Q components (Ŝ_{ideal}(tₙ)) of the digital baseband I/Q signal is shown by Equation (4):

$${\hat{S}}_{i d e a l} ( {t}_{n} ) = {S}_{i d e a l} ( {t}_{n} ) + \frac{{\sum }_{m = 0}^{M = 1} {n}_{m} ( {t}_{n} )}{M} \qquad ( 4 )$$

In Equation (4), S_{ideal}(tₙ) is the hypothetical ideal digital baseband I/Q signal, M is the number of repeating waveforms of the digital baseband I/Q signal, and tₙ is the nth sampling point, as discussed above. Also as mentioned above, the estimated total noise I/Q components (\hat{n}ₘ^{total}ₙ)) of the digital baseband I/Q signal are determined according to Equations (5A) and (5B):

$${\hat{n}}_{m}^{total} ( {t}_{n} ) = {s}_{m} ( {t}_{n} ) - {\hat{s}}_{ideal} ( {t}_{n} ) \qquad ( 5 A )$$

$${\hat{n}}_{m}^{total} ( {t}_{n} ) = \frac{( M - 1 ) {n}_{m} ( {t}_{n} ) - {\sum }_{i \neq m}^{M - 1} {n}_{i} ( {t}_{n} )}{M} \qquad ( 5 B )$$

Generally, to determine an accurate estimate of the actual RF test signal output by the DUT 210, the noise attributable to the DUT 210 must be added back to the signal I/Q provided by the coherent averaging at the signal I/Q module 234. This may be accomplished by corrected noise I/Q module 236, which determines what proportion of the total noise I/Q components at the noise I/Q module 235 is attributable to the DUT noise introduced by the DUT 210.

In the depicted embodiment, the corrected noise I/Q module 236 receives the total noise from the noise I/Q module 235 and the estimated instrument noise power (\hat{p}_{TI}) from the instrument noise power module 232, and determines the noise contributed by the DUT 210 to the RF test signal. This is done by determining the estimated noise power of the DUT 210 (\hat{p}_{DUT}) as the difference between the total noise power (\hat{p}ₜₒₜₐₗ) and the instrument noise power (\hat{p}_{TI}), as indicated by Equation (6):

$${\hat{ρ}}_{D U T} = {\hat{ρ}}_{total} - {\hat{ρ}}_{TI} \qquad ( 6 )$$

The instrument noise power (\hat{p}_{TI}) is estimated by the NFE module 231 and output by the instrument noise power module 232, as discussed above. The total noise power (\hat{p}ₜₒₜₐₗ) is estimated based on the estimated total noise I/Q components of the digital baseband I/Q signal according to Equation (7):

$${\hat{ρ}}_{total} = \frac{M}{M - 1} \{ \frac{{\sum }_{m} {\sum }_{n} {\hat{n}}_{m}^{t o t a l} ( {t}_{n} ) ( {\hat{n}}_{m}^{t o t a l} ( {t}_{n} ) )}{M} \} \qquad ( 7 )$$

The corrected noise I/Q module 236 then calculates a ratio between estimated DUT noise power (\hat{p}_{DUT}) and the estimated total noise power (\hat{p}ₜₒₜₐₗ) as the noise power ratio, and multiplies the total noise I/Q components from the noise I/Q module 235 by (square root of) the noise power ratio to determine corrected DUT noise I/Q components (\hat{n}ₘ^{DUT}(tₙ)) in the digital baseband I/Q signal, according to Equation (8):

$${\hat{n}}_{m}^{D U T} ( {t}_{n} ) = \sqrt{\frac{{\hat{ρ}}_{total} - {\hat{ρ}}_{TI}}{{\hat{ρ}}_{total}}} \times {\hat{n}}_{m}^{total} ( {t}_{n} ) \qquad ( 8 )$$

In Equation (8),

$$\frac{{\hat{ρ}}_{total} - {\hat{ρ}}_{TI}}{{\hat{ρ}}_{total}}$$

is the noise power ratio of the estimated DUT noise power and the estimated total noise power, and

$${\hat{n}}_{m}^{total} ( {t}_{n} )$$

is the estimated total noise I/Q components of the digital baseband I/Q signal.

A summation module 237 adds the DUT noise from the corrected noise I/Q module 236 and the ideal signal from the signal I/Q module 234 to estimate a noise corrected digital baseband I/Q signal, which includes the RF test signal output by the DUT 210 with only the noise introduced by the DUT 210, as shown in Equation (9):

$${s}_{m}^{n c} ( {t}_{n} ) = {\hat{s}}_{ideal} ( {t}_{n} ) + {\hat{n}}_{m}^{D U T} ( {t}_{n} ) \qquad ( 9 )$$

In other words, the noise introduced by the signal analyzer 220 has been removed from the digital baseband I/Q signal originally output by the signal analyzer 220. When M is large enough (e.g., at least 30), the ideal signal I/Q components (Ŝ_{ideal}(tₙ)) of the digital baseband I/Q signal are approximately equal to the ideal signal (S_{ideal}(tₙ)), and the corrected DUT noise I/Q components (\hat{n}ₘ^{DUT}(tₙ)) are approximately equal to the DUT noise (\hat{n}ₘ^{DUT}(tₙ)). Therefore, the noise corrected digital baseband I/Q signal (s^{nc}(tₙ)) may be approximated by Equation (10), as follows:

$${s}^{n c} ( {t}_{n} ) ≅ {s}_{ideal} ( {t}_{n} ) + {n}^{D U T} ( {t}_{n} ) \qquad ( 10 )$$

The corrected digital baseband I/Q signal correlates to the RF test signal output by the DUT 210 with only the noise introduced by the DUT 210. The corrected digital baseband I/Q signal is demodulated in order to recover the test data of the DUT 210 that modulated the RF test signal received by the signal analyzer 220. The demodulation may be performed by a receiver (not shown), for example, included in the signal analyzer 220, as would be apparent to one skilled in the art.

Various measurements may then be performed by the signal analyzer 220 on the demodulated corrected digital baseband I/Q signal (i.e., the test data). For example, the demodulated corrected digital baseband I/Q signal may be input to EVM_{DUT} module 238, which measures the EVM of the demodulated corrected digital baseband I/Q signal, where the EVM indicates RF performance of the DUT 210. As mentioned above, EVM provides a measure of error vectors in the I-Q plane between ideal constellation points and actual constellation points as received by the signal analyzer 220, thereby representing the difference between the ideal symbols and actual received symbols. The EVM_{DUT} module 238 may measure the EVM according to any of various EVM measurement techniques, as provided by applicable communication standards, as would be apparent to one skilled in the art.

Of course, other types of measurements may be performed on the demodulated corrected digital baseband I/Q signal, which benefit from removal of instrument noise, without departing from the scope of the present teachings. Such measurements may include measuring the constellation, the error spectrum, and the EVM versus symbols, for example. Also, the noise corrected demodulated I/Q signal improves receiving decoded bits of data from the corrected digital baseband I/Q signal.

Therefore, the various embodiments effectively extend the EVM floor of the signal analyzer 220. The I/Q noise correction corrects the instrument noise from I/Q capture and then extends the dynamic range of the signal analyzer 220 for best EVM performance. For example, the noise floor of the signal analyzer 220 for measuring EVM may be extended from about −51 dB to about −55 dB. The RF test signal output by the DUT 210 is a cyclical waveform, as mentioned above, and only the single signal analyzer 220 is required. Generally, the signal analyzer 220 captures the RF test signal over multiple periods and measures the instrument noise power in the same configuration. The coherent average over all signal periods is applied to get the estimated approximatively noise-free signal I/Q and the estimated total noise I/Q. The noise contribution by the signal analyzer 220 to the total noise I/Q is estimated and removed proportionally from the total noise I/Q to provide corrected noise I/Q. A noise corrected digital baseband I/Q signal is recovered by summing up the approximatively noise-free signal I/Q and the corrected noise I/Q.

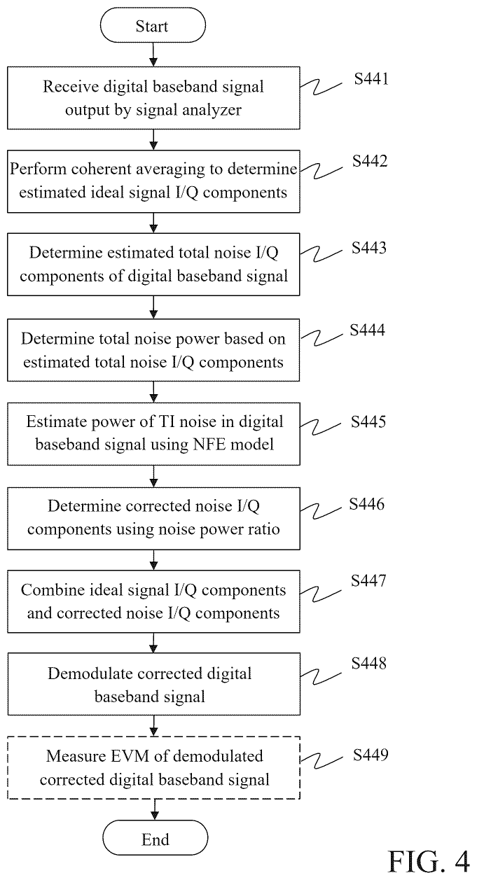

FIG. 4 is a flow diagram illustrating a method of compensating for noise introduced by a test instrument configured to measure a test signal received from DUT, according to a representative embodiment. The steps of FIG. 4 may be implemented at least in part by the processing unit 230 depicted in FIGS. 2A and 5, for example, where instructions for performing the various steps are stored on a non-transitory computer readable medium, such as memory 520 depicted in FIG. 5, for example.

Referring to FIG. 4, a digital baseband signal is received in block S441, where the digital baseband signal is the digital baseband I/Q signal output by a test instrument, such as a signal analyzer, as discussed above, in response to an RF test signal received by the test instrument from a DUT, where the RF test signal is modulated by DUT test data. The digital baseband signal has repeating waveforms, and includes an ideal signal and a total noise signal. The total noise signal includes DUT noise introduced by the DUT and test instrument (TI) noise introduced by the test instrument.

In block S442, coherent averaging is performed on the repeating waveforms of the digital baseband signal to determine estimated ideal signal I/Q components. That is, the coherent averaging causes the noise introduced by both the DUT and the test instrument to drop out. The estimated ideal signal I/Q components therefore have negligible noise, which is an amount small enough to have no practical effect on subsequent measurements. The coherent averaging includes synchronizing repeating waveforms of the digital baseband signal with timing offset, phase offset and magnitude mismatch, and averaging over the synchronized repeating waveforms of the digital baseband signal, providing the estimated ideal signal I/Q components of the digital baseband signal.

In block S443, estimated total noise I/Q components of the digital baseband signal are determined by subtracting the estimated ideal signal I/Q components determined in block S442 from the digital baseband signal received in block S441. The total noise I/Q components indicate DUT noise introduced by both the DUT and instrument noise introduced by the test instrument, as discussed above with reference to Equations (5A) and (5B).

In block S444, total noise power of the digital baseband signal is determined based on the estimated total noise I/Q components determined in block S443. The total noise power of the digital baseband signal is discussed above with reference to Equation (7).

In block S445, noise power of the instrument noise in the digital baseband signal, introduced by the test instrument, is estimated using an NFE model. The NFE model is a mathematical model that is based at least in part on current settings of the test instrument. The mathematical model is discussed above with reference to Equation (1). Because the NFE model is a mathematical model, the noise power of the instrument noise in the digital baseband signal may be estimated without disconnecting the DUT from the input of the test instrument, and without reconnecting the test instrument to a load to terminate the input.

In block S446, corrected noise I/Q components of the digital baseband signal are determined by determining a noise power ratio of estimated noise power of the DUT and the total noise power of the digital baseband signal, and applying the noise power ratio to the estimated total noise I/Q components.

In block S447, the estimated ideal signal I/Q components and the corrected noise I/Q components are combined to provide a corrected digital baseband signal that indicates noise only introduced by the DUT.

In block S447, the corrected digital baseband signal is demodulated to provide the test data of the DUT. The corrected digital baseband signal may be demodulated by a receiver, for example, which may part of the test instrument, as would be apparent to one skilled in the art.

In block S448, EVM of the demodulated corrected digital baseband signal of the DUT is optionally measured. The measured EVM provides an actual EVM of the DUT, without noise and/or EVM of the test instrument interfering. Of course, other types of measurements may be performed on the demodulated corrected digital baseband signal that benefit from removal of instrument noise, such as constellation measurements, error spectrum measurements, and EVM versus symbols measurements, for example.

FIG. 5 is a simplified block diagram of a representative processing unit, such as the processing unit 230 in FIG. 2A, according to a representative embodiment.

Referring to FIG. 5, processing unit 230 includes a processor 510, memory 520 for storing instructions executable by the processor 510 to implement the processes described herein, as well as a display 530 and an interface 540 to enable user interaction.

The processor 510 is representative of one or more processing devices, and is configured to execute software instructions to perform functions as described in the various embodiments herein. The processor 510 may be implemented by a general purpose computer, a central processing unit, a digital signal processor (DSP), a graphics processing unit (GPU), one or more processors, microprocessors or microcontrollers, a state machine, a programmable logic device, field programmable gate arrays (FPGAs), application specific integrated circuits (ASICs), or combinations thereof, using any combination of hardware, software, firmware, hard-wired logic circuits, or combinations thereof. The term “processor” encompasses an electronic component able to execute a program or machine executable instructions. References to a processor should be interpreted to include more than one processor or processing core, as in a multi-core processor, and/or parallel processors. Programs have software instructions performed by one or multiple processors that may be within the same computing device or which may be distributed across multiple computing devices.

The memory 520 may include a main memory and/or a static memory, where such memories may communicate with each other and the processor 510 via one or more buses. The memory 520 stores instructions which may be arranged in software/firmware modules and used to implement some or all aspects of methods and processes described herein, including the methods described above with reference to FIGS. 2A and 4, for example. The memory 520 may be implemented by any number, type and combination of random access memory (RAM) and read-only memory (ROM), for example, and may store various types of information, such as software algorithms, data based models including neural network based models, and computer programs, all of which are executable by the processor 510. The various types of ROM and RAM may include any number, type and combination of computer readable storage media, such as a disk drive, flash memory, an electrically programmable read-only memory (EPROM), an electrically erasable and programmable read only memory (EEPROM), registers, a hard disk, a removable disk, tape, compact disk read only memory (CD-ROM), digital versatile disk (DVD), floppy disk, blu-ray disk, a universal serial bus (USB) drive, or any other form of storage medium known in the art.

The memory 520 is a tangible storage medium for storing data and executable software instructions, and is non-transitory during the time software instructions are stored therein. As used herein, the term “non-transitory” is to be interpreted not as an eternal characteristic of a state, but as a characteristic of a state that will last for a period. The term non-transitory specifically disavows fleeting characteristics such as characteristics of a carrier wave or signal or other forms that exist only transitorily in any place at any time. The memory 520 may store software instructions and/or computer readable code that enable performance of various functions. The memory 520 may be secure and/or encrypted, or unsecure and/or unencrypted.

“Memory” is an example of computer-readable storage media, and should be interpreted as possibly being multiple memories or databases. The memory or database may for instance be multiple memories or databases local to the computer, and/or distributed amongst multiple computer systems or computing devices. A computer readable storage medium is defined to be any medium that constitutes patentable subject matter under 35 U.S.C. § 101 and excludes any medium that does not constitute patentable subject matter under 35 U.S.C. § 101. Examples of such media include non-transitory media such as computer memory devices that store information in a format that is readable by a computer or data processing system. More specific examples of non-transitory media include computer disks and non-volatile memories.

The display 530 may be a monitor such as a computer monitor, a television, a liquid crystal display (LCD), an organic light emitting diode (OLED), a flat panel display, a solid-state display, or a cathode ray tube (CRT) display, or an electronic whiteboard, for example. The display 530 may also provide a graphical user interface (GUI) for displaying and receiving information to and from the user.

The interface 540 may include a user and/or network interface for providing information and data output by the processor 510 and/or the memory 520 to the user and/or for receiving information and data input by the user. That is, the interface 540 enables the user to enter data and to control or manipulate aspects of the processes described herein, and also enables the processor 510 to indicate the effects of the user's control or manipulation. The interface 540 may connect one or more user interfaces, such as a mouse, a keyboard, a mouse, a trackball, a joystick, a haptic device, a microphone, a video camera, a touchpad, a touchscreen, voice or gesture recognition captured by a microphone or video camera, for example, or any other peripheral or control to permit user feedback from and interaction with the processor 510. The interface 540 may further include one or more of ports, disk drives, wireless antennas, or other types of receiver circuitry.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those having ordinary skill in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to an advantage.

Aspects of the present invention may be embodied as an apparatus, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer executable code embodied thereon.

While representative embodiments are disclosed herein, one of ordinary skill in the art appreciates that many variations that are in accordance with the present teachings are possible and remain within the scope of the appended claim set. The invention therefore is not to be restricted except within the scope of the appended claims.

1. A system for compensating for noise introduced by a test instrument configured to measure a radio frequency (RF) test signal received from a device under test (DUT), wherein the RF test signal is modulated by test data of the DUT, the system comprising:
a processing unit; and
a memory storing instructions that, when executed, cause the processing unit to:
receive a digital baseband signal with repeating waveforms output by the test instrument in response to the RF test signal received by the test instrument, wherein the digital baseband signal comprises an ideal signal and a total noise signal, wherein the total noise signal includes DUT noise introduced by the DUT and instrument noise introduced by the test instrument;
perform coherent averaging of the repeating waveforms of the digital baseband signal to determine estimated ideal signal in-phase/quadrature (I/Q) components, wherein the estimated ideal signal I/Q components have negligible noise;
determine estimated total noise I/Q components of the digital baseband signal by subtracting the estimated ideal signal I/Q components from the digital baseband signal;
determine total noise power of the digital baseband signal based on the estimated total noise I/Q components;
estimate noise power of the instrument noise in the digital baseband signal introduced by the test instrument using a noise figure extension (NFE) model based on at least settings of the test instrument;
determine corrected noise I/Q components of the digital baseband signal by determining a noise power ratio of estimated noise power of the DUT and the total noise power of the digital baseband signal, and applying the noise power ratio to the estimated total noise I/Q components; and
combine the estimated ideal signal I/Q components and the corrected noise I/Q components to provide a corrected digital baseband signal that indicates the DUT noise introduced by the DUT, without the instrument noise, wherein the corrected digital baseband signal is demodulated to provide the test data of the DUT.

2. The system of claim 1, wherein the instructions further cause the processing unit to measure error vector magnitude (EVM) of the test data of the DUT, wherein the measured EVM provides an actual EVM of the DUT.

3. The system of claim 1, wherein the NFE model estimates the noise power of the instrument noise based on signal attenuation introduced by the test instrument at the settings, a predetermined loss function of the test instrument, a predetermined gain function compensating for the signal attenuation, and hardware noise contributed by the test instrument.

4. The system of claim 1, wherein the NFE model comprises a mathematical model that estimates the noise power of the instrument noise as follows:
$${\hat{ρ}}_{TI} = 1 / Loss ( f ) * 1 / Atten * [ e 1 + e 2 / GC ( f ) ] ,$$
wherein \hat{p}_{TI} is the estimated noise power of the instrument noise at an RF reference input plane of the test instrument, Atten is signal attenuation introduced by the test instrument at the settings, Loss(f) is a predetermined loss function from the RF reference input plane to a mixer of the test instrument, GC(f) is a predetermined gain function compensating for the signal attenuation, e1 is front-end noise contributed by front-end hardware of the test instrument, and e2 is backend noise contributed by at least an analog to digital converter (ADC) of the test instrument.

5. The system of claim 4, wherein performing coherent averaging of the repeating waveforms of the digital baseband signal to determine the estimated ideal signal I/Q components of the digital baseband signal comprises:
synchronizing M repeating waveforms of the digital baseband signal with timing offset, phase offset and magnitude mismatch; and
averaging over the synchronized M repeating waveforms of the digital baseband signal to determine the estimated ideal signal I/Q components of the digital baseband signal.

6. The system of claim 5, wherein averaging over the synchronized M repeating waveforms of the digital baseband signal to determine the estimated ideal signal I/Q components of the digital baseband signal comprises:
$${\hat{S}}_{i d e a l} ( {t}_{n} ) = {S}_{i d e a l} ( {t}_{n} ) + \frac{{\sum }_{m = 0}^{M = 1} {n}_{m} ( {t}_{n} )}{M} ,$$
wherein Ŝ_{ideal}(tₙ) is the estimated ideal signal I/Q components of the digital baseband signal, S_{ideal}(tₙ) is a hypothetical ideal noise-free signal output by the DUT, M is the number of repeating waveforms of the digital baseband signal, and tₙ is an nth sampling point.

7. The system of claim 6, wherein determining the estimated total noise I/Q components of the digital baseband signal output by test instrument comprises:
$$\begin{matrix}{\hat{n}}_{m}^{total} ( {t}_{n} ) = {s}_{m} ( {t}_{n} ) - {\hat{s}}_{ideal} ( {t}_{n} ) \\ {\hat{n}}_{m}^{total} ( {t}_{n} ) = \frac{( M - 1 ) {n}_{m} ( {t}_{n} ) - {\sum }_{i \neq m}^{M - 1} {n}_{i} ( {t}_{n} )}{M} ,\end{matrix}$$
wherein
$${\hat{n}}_{m}^{total} ( {t}_{n} )$$
is the estimated total noise I/Q components of the digital baseband signal output by test instrument.

8. The system of claim 7, wherein determining the total noise power of the digital baseband signal comprises:
$${\hat{ρ}}_{total} = \frac{M}{M - 1} \{ \frac{{\sum }_{m} {\sum }_{n} {\hat{n}}_{m}^{t o t a l} ( {t}_{n} ) ( {\hat{n}}_{m}^{t o t a l} ( {t}_{n} ) )}{M} \} ,$$
wherein \hat{p}ₜₒₜₐₗ is the estimated noise power of the estimated total noise I/Q components, and
wherein determining the corrected noise I/Q components of the digital baseband signal comprises:
$${\hat{n}}_{m}^{D U T} ( {t}_{n} ) = \sqrt{\frac{{\hat{ρ}}_{total} - {\hat{ρ}}_{TI}}{{\hat{ρ}}_{total}}} \times {\hat{n}}_{m}^{total} ( {t}_{n} ) ,$$
wherein
$${\hat{n}}_{m}^{D U T} ( {t}_{n} )$$
is the corrected noise I/Q components, \hat{p}_{TI} is the estimated noise power of the instrument noise provided by the NFE model,
$$\frac{{\hat{ρ}}_{total} - {\hat{ρ}}_{TI}}{{\hat{ρ}}_{total}}$$
is the noise power ratio of the estimated noise power of the DUT and the total noise power of the digital baseband signal.

9. The system of claim 8, wherein combining the estimated ideal signal I/Q components and the corrected noise I/Q components to provide the corrected digital baseband signal comprises:
$${s}_{m}^{nc} ( {t}_{n} ) = {\hat{S}}_{ideal} ( {t}_{n} ) + {\hat{n}}_{m}^{DUT} ( {t}_{n} ) ,$$
wherein
$${s}_{m}^{nc} ( {t}_{n} )$$
is the corrected digital baseband signal corresponding to a corrected RF test signal of the DUT.

10. The system of claim 1, wherein the settings of the test instrument used for the NFE model include at least center frequency, bandwidth, attenuation, and IF gain.

11. A method of compensating for noise introduced by a test instrument configured to measure a radio frequency (RF) test signal received from a device under test (DUT), wherein the RF test signal is modulated by test data of the DUT, the method comprising:
receiving a digital baseband signal with repeating waveforms output by the test instrument in response to the RF test signal received by the test instrument, wherein the digital baseband signal comprises an ideal signal and a total noise signal, and wherein the total noise signal includes DUT noise introduced by the DUT and instrument noise introduced by the test instrument;
performing coherent averaging of the repeating waveforms of the digital baseband signal to determine estimated ideal signal in-phase/quadrature (I/Q) components, wherein the estimated ideal signal I/Q components have negligible noise;
determining estimated total noise I/Q components of the digital baseband signal by subtracting the estimated ideal signal I/Q components from the digital baseband signal;
determining total noise power of the digital baseband signal based on the estimated total noise I/Q components;
estimating noise power of the instrument noise in the digital baseband signal introduced by the test instrument using a noise figure extension (NFE) model based on at least settings of the test instrument;
determining corrected noise I/Q components of the digital baseband signal by determining a noise power ratio of estimated noise power of the DUT and the total noise power of the digital baseband signal, and applying the noise power ratio to the estimated total noise I/Q components; and
combining the estimated ideal signal I/Q components and the corrected noise I/Q components to provide a corrected digital baseband signal that indicates the DUT noise introduced by the DUT, without the instrument noise, wherein the corrected digital baseband signal is demodulated to provide the test data of the DUT.

12. The method of claim 11, further comprising:
measuring error vector magnitude (EVM) of the test data of the DUT, wherein the measured EVM provides an actual EVM of the DUT.

13. The method of claim 11, wherein the NFE model estimates the noise power of the instrument noise based on signal attenuation introduced by the test instrument at the settings, a predetermined loss function of the test instrument, a predetermined gain function compensating for the signal attenuation, and hardware noise contributed by the test instrument.

14. The method of claim 11, wherein the NFE model comprises a mathematical model that estimates the noise power of the instrument noise as follows:
$${\hat{ρ}}_{TI} = Loss ( f ) * Atten * [ e 1 + e 2 / GC ( f ) ] ,$$
wherein \hat{p}_{TI} is the estimated noise power of the instrument noise at an RF reference input plane of the test instrument, Atten is signal attenuation introduced by the test instrument at the settings, Loss(f) is a predetermined loss function from the RF reference input plane to a mixer of the test instrument, GC(f) is a predetermined gain function compensating for the signal attenuation, e1 is front-end noise contributed by front-end hardware of the test instrument, and e2 is backend noise contributed by at least an analog to digital converter (ADC) of the test instrument.

15. A non-transitory computer readable medium storing instructions for compensating for noise introduced by a test instrument configured to measure a radio frequency (RF) test signal received from a device under test (DUT), wherein the RF test signal is modulated by test data of the DUT, wherein when executed by a processing unit, the instructions cause the processing unit to:
receive a digital baseband signal with repeating waveforms output by the test instrument in response to the RF test signal received by the test instrument, wherein the digital baseband signal comprises an ideal signal and a total noise signal, and wherein the total noise signal includes DUT noise introduced by the DUT and instrument noise introduced by the test instrument;
perform coherent averaging of the repeating waveforms of the digital baseband signal to determine estimated ideal signal in-phase/quadrature (I/Q) components, wherein the estimated ideal signal I/Q components have negligible noise;
determine estimated total noise I/Q components of the digital baseband signal by subtracting the estimated ideal signal I/Q components from the digital baseband signal;
determine total noise power of the digital baseband signal based on the estimated total noise I/Q components;
estimate noise power of the instrument noise in the digital baseband signal introduced by the test instrument using a noise figure extension (NFE) model based on at least settings of the test instrument;
determine corrected noise I/Q components of the digital baseband signal by determining a noise power ratio of estimated noise power of the DUT and the total noise power of the digital baseband signal, and applying the noise power ratio to the estimated total noise I/Q components; and
combine the estimated ideal signal I/Q components and the corrected noise I/Q components to provide a corrected digital baseband signal that indicates the DUT noise introduced by the DUT, without the instrument noise, and wherein the corrected digital baseband signal is demodulated to provide the test data of the DUT.

16. The non-transitory computer readable medium of claim 15, wherein the NFE model estimates the noise power of the instrument noise based on signal attenuation introduced by the test instrument at the settings, a predetermined loss function of the test instrument, a predetermined gain function compensating for the signal attenuation, and hardware noise contributed by the test instrument.

17. The non-transitory computer readable medium of claim 15, wherein the NFE model comprises a mathematical model that estimates the noise power of the instrument noise as follows:
$${\hat{ρ}}_{TI} = 1 / Loss ( f ) * 1 / Atten * [ e 1 + e 2 / GC ( f ) ] ,$$
wherein \hat{p}_{TI} is the estimated noise power of the instrument noise at an RF reference input plane of the test instrument, Atten is signal attenuation introduced by the test instrument at the settings, Loss(f) is a predetermined loss function from the RF reference input plane to a mixer of the test instrument, GC(f) is a predetermined gain function compensating for the signal attenuation, e1 is front-end noise contributed by front-end hardware of the test instrument, and e2 is backend noise contributed by at least an analog to digital converter (ADC) of the test instrument.

18. The non-transitory computer readable medium of claim 17, wherein performing coherent averaging of the repeating waveforms of the digital baseband signal to determine the estimated ideal signal I/Q components of the digital baseband signal comprises:
synchronizing M repeating waveforms of the digital baseband signal with timing offset, phase offset and magnitude mismatch; and
averaging over the synchronized M repeating waveforms of the digital baseband signal to determine the estimated ideal signal I/Q components of the digital baseband signal.

19. The non-transitory computer readable medium of claim 18, wherein averaging over the synchronized M repeating waveforms of the digital baseband signal to determine the estimated ideal signal I/Q components of the digital baseband signal comprises:
$${\hat{S}}_{ideal} ( {t}_{n} ) = {S}_{ideal} ( {t}_{n} ) + \frac{{\sum }_{m = 0}^{M = 1} {n}_{m} ( {f}_{n} )}{M} ,$$
wherein Ŝ_{ideal}(tₙ) is the estimated ideal signal I/Q components of the digital baseband signal, S_{ideal}(tₙ) is a hypothetical ideal noise-free signal output by the DUT, M is the number of repeating waveforms of the digital baseband signal, and tₙ is an nth sampling point, and
wherein determining the estimated total noise I/Q components of the digital baseband signal output by test instrument comprises:
$${\hat{n}}_{m}^{total} ( {t}_{n} ) = {s}_{m} ( {t}_{n} ) - {\hat{s}}_{ideal} ( {t}_{n} )$$
$${\hat{n}}_{m}^{total} ( {t}_{n} ) = \frac{( M - 1 ) {n}_{m} ( {t}_{n} ) - {\sum }_{i \neq m}^{M - 1} {n}_{i} ( {t}_{n} )}{M} ,$$
wherein
$${\hat{n}}_{m}^{total} ( {t}_{n} )$$
is the estimated total noise I/Q components of the digital baseband signal output by test instrument.

20. The non-transitory computer readable medium of claim 19, wherein determining the total noise power of the digital baseband signal comprises:
$${\hat{ρ}}_{total} = \frac{M}{M - 1} \{ \frac{{\sum }_{m} {\sum }_{n} {\hat{n}}_{m}^{total} ( {t}_{n} ) ( {\hat{n}}_{m}^{total} ( {t}_{n} ) )}{M} \} ,$$
wherein \hat{p}ₜₒₜₐₗ is the estimated noise power of the estimated total noise I/Q components, and
wherein determining the corrected noise I/Q components of the digital baseband signal comprises:
$${\hat{n}}_{m}^{DUT} ( {t}_{n} ) = \sqrt{\frac{{\hat{ρ}}_{total} - {\hat{ρ}}_{TI}}{{\hat{ρ}}_{total}}} \times {\hat{n}}_{m}^{total} ( {t}_{n} ) ,$$
wherein
$${\hat{n}}_{m}^{DUT} ( {t}_{n} )$$
is the corrected noise I/Q components, \hat{p}_{TI} is the estimated noise power of the instrument noise provided by the NFE model,
$$\frac{{\hat{ρ}}_{total} - {\hat{ρ}}_{TI}}{{\hat{ρ}}_{total}}$$
is the noise power ratio of the estimated noise power of the DUT and the total noise power of the digital baseband signal, and
wherein combining the estimated ideal signal I/Q components and the corrected noise I/Q components to provide the corrected digital baseband signal comprises:
$${s}_{m}^{nc} ( {t}_{n} ) = {\hat{S}}_{ideal} ( {t}_{n} ) + {\hat{n}}_{m}^{DUT} ( {t}_{n} ) ,$$
wherein
$${s}_{m}^{nc} ( {t}_{n} )$$
is the corrected digital baseband signal corresponding to a corrected RF test signal of the DUT.
